(19) United States
(12) Patent Application Publication
(10) Pub. No.: US 2004/0155348 A1
(43) Pub. Date: Aug. 12, 2004

(54) Barrier structure for copper metallization and method for the manufacture thereof

(75) Inventor: Jae Suk Lee, Seoul (KR)

Correspondence Address: PILLSBURY WINTHROP, LLP, P.O. BOX 10500, MCLEAN, VA, 22102, US

(73) Assignee: Dongbu Electronics Co., Ltd., Seoul (KR)

(21) Appl. No.: 10/730,941

(22) Filed: Dec. 10, 2003

(30) Foreign Application Priority Data
Dec. 30, 2002 (KR) 10-2002-0086358

(51) Int. Cl. H01L 23/48

(52) U.S. Cl. 257/758

(57) ABSTRACT

A copper metallization structure includes a dielectric pattern formed on a surface of a substrate. Sequentially formed on the dielectric pattern are a first Ru layer and an oxide film. The copper metallization structure further includes a second Ru layer formed on the oxide film and a Cu layer formed on the second Ru layer.

### FIELD OF THE INVENTION

The present invention relates to an integrated circuit processing; and, more particularly, to a barrier structure for copper metallization and method for the manufacture thereof.

### BACKGROUND OF THE INVENTION

On VLSI and ULSI semiconductor chips, Al and Al alloys are used as the conventional chip wiring materials. The incorporation of copper(Cu) and Cu alloys as the chip wiring materials results in improved chip performance and superior reliability when compared to Al and Al alloys. Cu is widely used as a metallization material reducing RC delay because it has lower electrical resistivity and higher conductivity among semiconductor wiring materials. Because of its lower resistivity, it allows lower energy consumption and heat dissipation.

A damascene process is widely used for Cu metallization because it requires fewer processing steps than other methods and offers a higher yield. It is also particularly well-suited to metals such as Cu that cannot readily be patterned by plasma etching. The damascene process is a method for forming metal lines on integrated circuits. It involves formation of inlaid metal lines in trenches and vias formed in a dielectric layer(inter-metal dielectric).

However, a problem with Cu is that Cu readily diffuses into nearly all materials used in Si devices, causing degrading of characteristics of the devices. Moreover, it is required to prevent leakage between metal lines because a pitch between metal lines is narrower according to a higher density integration.

Therefore, Cu must be completely isolated from the devices formed on the silicon substrate below. To accomplish this isolation, i.e., to prevent diffusion of Cu, a diffusion barrier is required.

A variety of materials, e.g., titanium(Ti), titanium nitride(TiN), tantalum(Ta) and tantalum nitride(TaN), has been proposed as Cu diffusion barriers. However, these Cu diffusion barriers have certain drawbacks. A Cu diffusion barrier using Ti and TiN has a higher electric conductivity but with poor barrier characteristics. On the other hand, a Cu diffusion barrier made of Ta and TaN has good barrier characteristics but with a lower electric conductivity.

### SUMMARY OF THE INVENTION

It is, therefore, an object of the present invention to provide a Cu metallization structure with an improved diffusion barrier and a method for the manufacture thereof.

### BRIEF DESCRIPTION OF THE DRAWINGS

The above and other objects and features of the present invention will become apparent from the following description of the preferred embodiment given in conjunction with the accompanying drawings, in which:

FIG. 1A shows a cross-sectional view illustrating a process of forming a dielectric pattern on a surface of a substrate and forming a first Ru layer on the dielectric pattern in accordance with the preferred embodiment of the present invention;

FIG. 1B describes a cross-sectional view showing a process of forming an oxide film in the surface region of the first Ru layer shown in FIG. 1A;

FIG. 1C is a cross-sectional view depicting a process of forming a second Ru layer on the oxide film of FIG. 1B; and

FIG. 1D provides a cross-sectional view representing a process of forming a Cu layer on the second Ru layer shown in FIG. 1C.

### DETAILED DESCRIPTION OF THE PREFERRED EMBODIMENTS

A Cu diffusion barrier in accordance with the present invention formed of Ru and Ru oxide has a higher electric conductivity and also improved barrier characteristics, compared with those of the conventional Cu diffusion barriers made of Ti, TiN, Ta, TaN, and the like. Furthermore, the barrier of the present invention has a triple layer structure, so that a deterioration of barrier characteristics is reduced and various applications are possible.

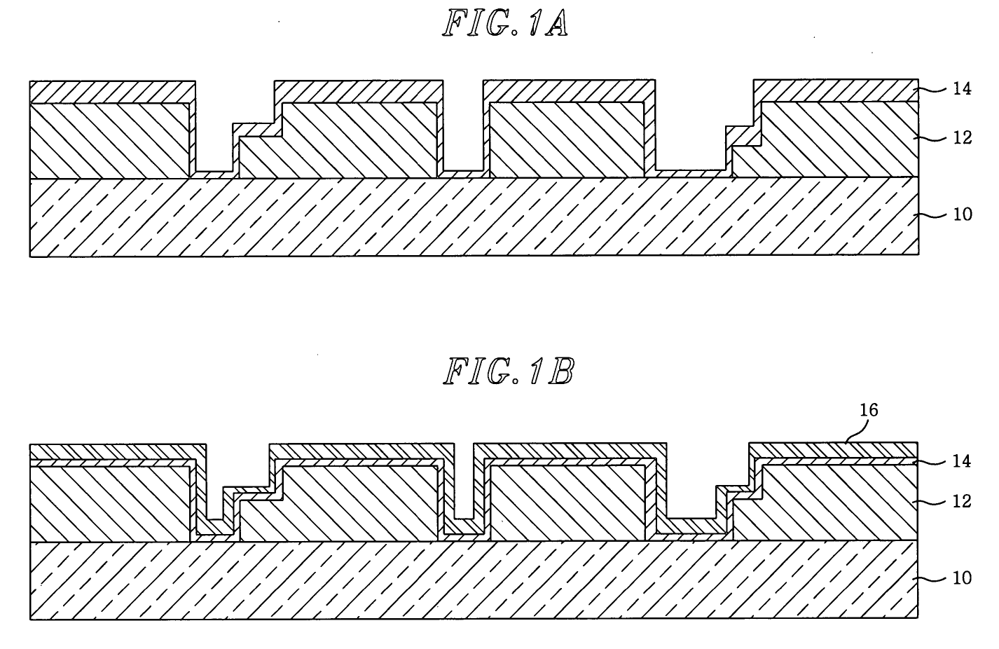

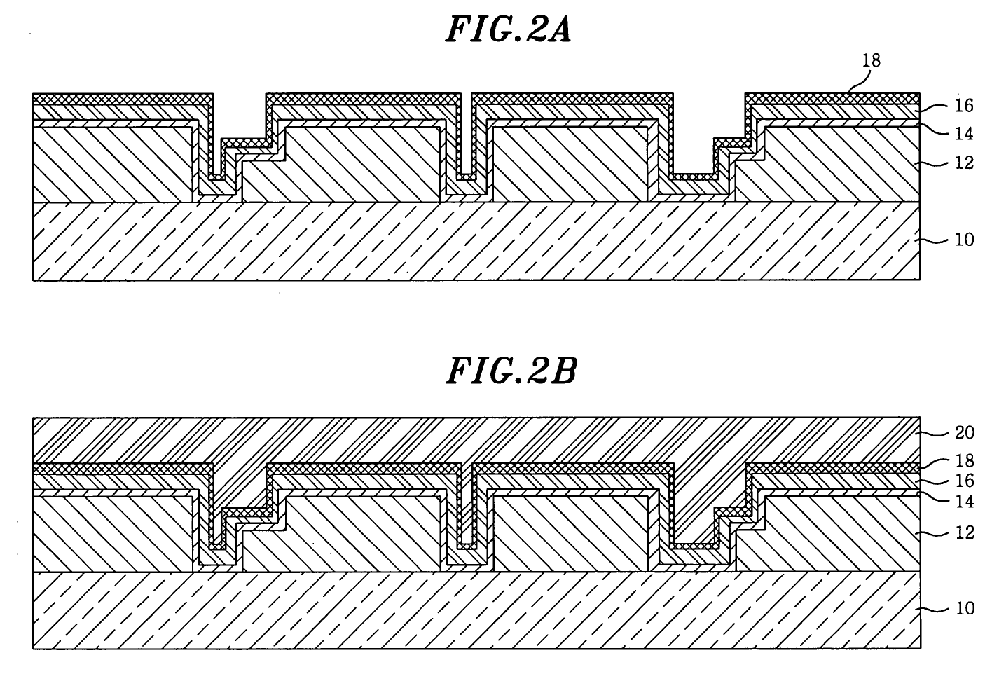

FIG. 1A illustrates a process of forming a dielectric pattern 12 on a surface of a substrate 10 and forming a first Ru layer 14 on the dielectric pattern 12. For example, the substrate 10 is a silicon substrate, on which a manufacturing process of transistors(TRs) is completed. First, the dielectric pattern 12 formed of, e.g., Si oxide or nitride, is formed on the surface of the substrate 10. Then, the first Ru layer 14 is deposited by using a sputtering or a CVD(chemical vapor deposition) process and has a thickness of up to 1000 angstroms.

The preferred thickness of the first Ru layer 14 is in a range from about 80 angstroms to about 120 angstroms, more preferably about 100 angstroms. Further, the temperature of about 400° C. and pressure, in case of the CVD process, ranging from about 0.1 torr to about 5 torr are preferred to form the fist Ru layer 14. In case of employing the sputtering, the preferred pressure is in a range from about 1 mtorr to about 10 mtorr.

Referring to FIG. 1B, a process of forming an oxide film 16 in the surface region of the first Ru layer 14 is described. The oxide film 16 being in the form of RuₓO_{y} is formed by a plasma treatment by using N₂O or O₂.

The preferred thickness of the oxide film 16 of RuₓO_{y} is about 250 angstroms, which is obtained by oxidizing the upper part, e.g., about 50 angstroms, of the first Ru layer 14. In other words, the plasma treatment is performed on the upper part of the first Ru layer 14 to thereby form the oxide film 16 made of RuₓO_{y}. In the preferred embodiment of the present invention, the range of x is preferably from about 0.7 to about 1.3, the range of y is preferably from about 1.6 to about 2.3 and the ratio of x:y=1:2 is preferred.

In the plasma treating process for the fabrication of RuₓO_{y}, the temperature of about 400° C., the pressure in a range from about 0.1 torr to about 5 torr and electric power ranging from about 200 watt to about 700 watt are preferred. Further, a He/Ar mixture gas is preferably used as a carrier gas and the reaction gas is N₂O or O₂.

FIG. 1C shows a process of forming a second Ru layer 18 on the oxide film 16. In a similar manner in FIG. 1A, the second Ru layer 18 is also deposited using the sputtering or the CVD(Chemical Vapor Deposition) process and has a thickness of up to 1000 angstroms. The preferred thickness of the second Ru layer 18 is about 50 angstroms and the forming condition is similar to that of the first Ru layer 14.

FIG. 1D represents a process of forming a Cu layer 20 on the second Ru layer 18. The Cu layer 20 may be preferably deposited by plating as in the prior art. The final structure shown in FIG. 1D may be planarized by CMP(Chemical Mechanical Planarization) and further processes can be performed thereon to complete the device fabrication.

The present invention describes a structure and method for a copper diffusion barrier capable of preventing the diffusion of copper into underlayers.

RuₓO_{y}, preferably in the form of RuO₂, used in the present invention is an oxide, but it has a high conductivity. Therefore, it is widely used as an electrode material of high-k material, e.g., PZT(lead-zirconium-titanium), BST(barium-strontium-titanate), and the like, k being a dielectric constant.

The oxide film 16 of RuₓO_{y} serves as a stuffing barrier for the Cu layer 20; the Ru layers 14 and 18 are sacrificial barriers for the Cu layer 20. The stuffing barrier used herein denotes a hard barrier that prevents the diffusion of Cu. The composition of the stuffing barrier remains unchanged. The sacrificial barrier used herein represents a barrier that suppresses the diffusion of Cu by changing the composition thereof.

While the invention has been shown and described with respect to the preferred embodiments, it will be understood by those skilled in the art that various changes and modifications may be made without departing from the spirit and scope of the invention as defined in the following claims.

What is claimed is:

1. A copper metallization structure, comprising:
a dielectric pattern formed on a surface of a substrate;
a first Ru layer formed on the dielectric pattern;
an oxide film formed in a surface region of the first Ru layer;
a second Ru layer formed on the oxide film; and
a Cu layer formed on the second Ru layer.

2. The copper metallization structure of claim 1, wherein the substrate is a silicon substrate.

3. The copper metallization structure of claim 1, wherein the first Ru layer and the second Ru layer are formed by using a sputtering or CVD(chemical vapor deposition) and has a thickness in a range from about 80 angstroms to about 120 angstroms.

4. The copper metallization structure of claim 1, wherein the oxide film is made of RuₓO_{y} formed by a plasma treatment using N₂O or O₂.

5. The copper metallization structure of claim 4, wherein the thickness of the oxide film is about 250 angstroms, which is obtained by oxidizing an upper part of the first Ru layer.

6. The copper metallization structure of claim 4, wherein the ratio of x:y=1:2.

7. A method for copper metallization, comprising the steps of:
forming a dielectric pattern on a surface of a substrate;
forming a first Ru layer on the dielectric pattern;
forming an oxide film in a surface region of the first Ru layer;
forming a second Ru layer on the oxide film; and
forming a Cu layer on the second Ru layer.

8. The method of claim 7, wherein the substrate is a silicon substrate.

9. The method of claim 7, wherein the first Ru layer and the second Ru layer are formed by using a sputtering or CVD(chemical vapor deposition) and has a thickness in a range from about 80 angstroms to about 120 angstroms.

10. The method of claim 7, wherein the oxide film is made of RuₓO_{y} formed by a plasma treatment using N₂O or O₂.

11. The method of claim 10, wherein the thickness of the oxide film is about 250 angstroms, which is obtained by oxidizing an upper part of the first Ru layer.

12. The method of claim 10, wherein the ratio of x:y=1:2.
